(19) United States
(12) Patent Application Publication
(10) Pub. No.: US 2025/0266804 A1
(43) Pub. Date: Aug. 21, 2025

(54) SULFUR HEXAFLUORIDE FILLED SURFACE ACOUSTIC WAVE (SAW) THIN-FILM ACOUSTIC PACKAGE (TFAP) DOMES

(71) Applicant: RF360 SINGAPORE PTE. LTD., Singapore (SG)

(72) Inventor: Valentin Albrecht WEIPPERT, München (DE)

(21) Appl. No.: 18/582,471

(22) Filed: Feb. 20, 2024

(51) Int. Cl. H03H 9/02; H03H 3/08; H03H 9/10; H03H 9/25; H03H 9/64

(52) U.S. Cl. CPC H03H 9/02818; H03H 3/08; H03H 9/1085; H03H 9/25; H03H 9/6483

(57) ABSTRACT

Certain aspects of the present disclosure provide a surface acoustic wave (SAW) device. The SAW device may include a piezoelectric layer, and an interdigital transducer (IDT) disposed above the piezoelectric layer. The IDT may include a plurality of fingers. A cap layer may be disposed above the IDT. A cavity may be formed between the IDT and the cap layer. A material such as sulfur hexafluoride (SF₆) may be disposed above and between the plurality of fingers of the IDT within the cavity.

### BACKGROUND

### Field of the Disclosure

Certain aspects of the present disclosure relate generally to electronic components and, more particularly, to surface acoustic wave (SAW) devices.

### Description of Related Art

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users.

These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

Today, surface acoustic wave (SAW) or bulk acoustic wave (BAW) components may be used in wireless communication devices, such as for implementing RF filters. In SAW technology, the acoustic wave propagates laterally on a surface of a piezoelectric substrate, with the movement of the piezoelectric generated by metal interdigital transducers (IDTs) on the surface. The wavelength of the acoustic wave may be defined by the pitch (e.g., the width of the metal finger and gap) of the IDT. In BAW technology, the acoustic wave propagates vertically through a three-dimensional structure, with an electric field applied through electrodes above and below a piezoelectric material. The wavelength, in this case, is defined by the thickness of the piezoelectric material.

In one type of SAW device, a surface acoustic wave is generated by an input IDT and detected by an output IDT. In another type of SAW device, the acoustic energy may be confined using reflectors on either side of the IDT. A planar resonant cavity created between two mirrors consisting of reflecting metal strips can also be used to trap the acoustic energy.

As the number of frequency bands used in wireless communications increases and as the desired frequency band of filters widen, the performance of acoustic filters increases in importance in order to reduce losses and increase overall performance of electronic devices. Acoustic filters with improved performance, particularly filters with reduced intermodulation distortion, are therefore sought after.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include implementation of surface acoustic wave (SAW) technology.

Certain aspects of the present disclosure provide a SAW device including: a piezoelectric layer; an interdigital transducer (IDT) disposed above the piezoelectric layer where the IDT includes a plurality of fingers; a cap layer disposed above the IDT where a cavity is formed between the IDT and the cap layer; and a material having a dielectric strength value exceeding a first threshold disposed above and between the plurality of fingers of the IDT within the cavity.

Certain aspects of the present disclosure provide a wireless device including: a radio frequency (RF) circuit; and a SAW device coupled to the RF circuit. The SAW device includes a piezoelectric layer; an IDT disposed above the piezoelectric layer where the IDT includes a plurality of fingers; a cap layer is disposed above the IDT where a cavity is formed between the IDT and the cap layer; and a material having a dielectric strength value exceeding a first threshold is disposed above and between the plurality of fingers of the IDT within the cavity. The RF circuit includes a transmit path and a receive path, and the SAW device forms a portion of a duplexer coupled to an output of the transmit path and to an input of the receive path. The RF circuit includes a low-noise amplifier (LNA), and the SAW device is coupled to an output of the LNA.

Certain aspects of the present disclosure provide a method of fabricating a SAW device. The method includes forming an IDT above a piezoelectric layer where the IDT includes a plurality of fingers; and forming a cap layer above the IDT such that a cavity is formed between the IDT and the cap layer where a material having a dielectric strength value exceeding a first threshold is disposed above and between the plurality of fingers of the IDT within the cavity.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a diagram of a perspective view of an example electroacoustic device, in which certain aspects of the present disclosure may be practiced.

FIG. 1B is a diagram of a side view of the example electroacoustic device of FIG. 1A.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIG. 3A is a diagram of a perspective view of an example electroacoustic device, in which certain aspects of the present disclosure may be practiced.

FIG. 3B is a diagram of a side view of an example electroacoustic device, in which certain aspects of the present disclosure may be practiced.

FIG. 4 illustrates a schematic diagram and implementation of an electroacoustic filter circuit, in which certain aspects of the present disclosure may be practiced.

FIG. 5 is a diagram of a perspective view of an example surface acoustic wave (SAW) device or filter, in which certain aspects of the present disclosure may be practiced.

FIG. 6 is a flow diagram depicting example operations for fabricating a SAW device, in which certain aspects of the present disclosure may be practiced.

FIG. 7 is a functional block diagram of at least a portion of an example simplified wireless transceiver circuit in which an electroacoustic filter circuit may be employed.

FIG. 8 is a diagram of an environment that includes an electronic device having a wireless transceiver such as the transceiver circuit of FIG. 7.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

As noted above, various electronic devices depend on wireless communications for many of their functions. Wireless communication transceivers used in these electronic devices may include multiple radio frequency (RF) filters for filtering a signal for a particular frequency or range of frequencies. For example, electroacoustic devices (e.g., acoustic filters) may be used for filtering high-frequency signals in many applications.

As noted above, surface acoustic wave (SAW) devices or filters may be used in wireless communication devices, such as for implementing RF filters. In SAW technology, an acoustic wave propagates laterally on a surface of a piezoelectric layer or substrate, with a movement of the piezoelectric generated by metal interdigital transducer (IDT) on the surface of the piezoelectric layer. The IDT may include multiple conductive fingers. A wavelength of the acoustic wave may be defined by a pitch (e.g., a width of each metal finger) of the IDT.

In some cases, one or more tests may be performed on the SAW devices. The one or more tests may include electrostatic discharge (ESD) tests, compression tests, and the like. The EDS test may be a process of testing a device's resistance to ESD. ESD may occur when two electrically charged objects may contact each other, are involved in an electrical short, or suffer a dielectric breakdown. This results in a sudden flow of electricity. The compression test may be a test to determine a device tolerance towards increasing applied power levels.

At a certain input power (e.g., which may be associated with or during the compression tests) and/or applied voltage (e.g., which may be associated with or during the ESD tests), the SAW device or filter may experience catastrophic failure through arcing (e.g., a formation of an electric arc), which may create an open or short circuit, and thereby severely degrading a passband (e.g., a range of frequencies or wavelengths that can pass through the SAW device). This may transpire due to low ESD and poor compression behavior of the SAW device, which may be due to continuous shrinkage (e.g., of size) of the SAW device as well as higher power/frequency operating requirements of the SAW device (e.g., high heating may worsen power durability and the compression behavior of the SAW device).

Arcing at the SAW device may happen due to multiple reasons. In one case, there may be a dielectric breakdown of the piezoelectric substrate (e.g., at the certain input power and/or the applied voltage), which may cause subsequent heating and melting of surrounding structures of the SAW device. In another case, increased conductivity/carrier concentration of the piezoelectric substrate through heating (e.g., from the applied voltage/power) may create some conductive areas in the SAW device. These areas may further heat up through ohmic losses once a current is established, and this may lead to a failure of the SAW device. In yet another case, the arcing may be through a gas phase and it may cause a dielectric breakdown with subsequent heating and melting of finger structures of the IDT and/or the piezoelectric substrate.

To achieve better ESD performance/handling and compression behavior of the SAW device, techniques described herein propose to fill a thin-film acoustic package (TFAP) dome or cavity of the SAW device with sulfur hexafluoride (SF₆). The TFAP dome or cavity may be between the multiple conductive fingers of the IDT and a layer (e.g., a cap layer) of the SAW device. The presence of the SF₆ may potentially improve the ESD performance/handling and compression behavior of the SAW device by creating a dielectric barrier hindering arching through the gas phase without additionally mass-loading the fingers of the IDT. The SF₆ may be used in high frequency and high voltage applications as an insulating gas due to its high dielectric strength.

### Example Electroacoustic Device

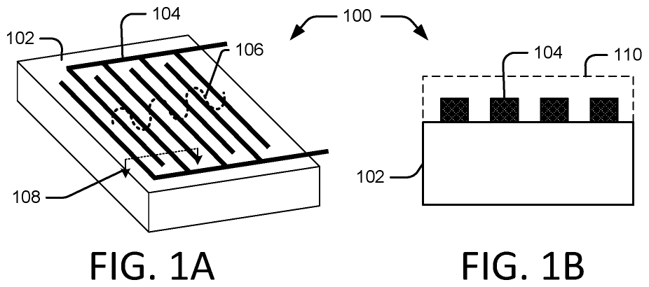

FIG. 1A is a diagram of a perspective view of an example electroacoustic device 100. The electroacoustic device 100 may be configured as or be a portion of a SAW resonator (or SAW device). In certain descriptions herein, the electroacoustic device 100 may be referred to as the SAW resonator. However, there may be other electroacoustic device types that may be constructed based on the principles described herein.

The electroacoustic device 100 includes an electrode structure 104, that may be referred to as an interdigital transducer (IDT), on a surface of a piezoelectric material 102. The electrode structure 104 generally includes first and second comb-shaped electrode structures (conductive and generally metallic) with electrode fingers extending from two busbars towards each other arranged in an interlocking manner in between the two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a side view of the electroacoustic device 100 of FIG. 1A along a cross-section 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO₃), lithium niobite (LiNbO₃), doped variants of these, other piezoelectric materials, or other crystals. It should be appreciated that more complicated layer stacks including layers of various materials may be possible within the stack. For example, optionally, a temperature compensation layer 110 denoted by the dashed lines may be disposed above the electrode structure 104.

The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip chip or other techniques) may also be included.

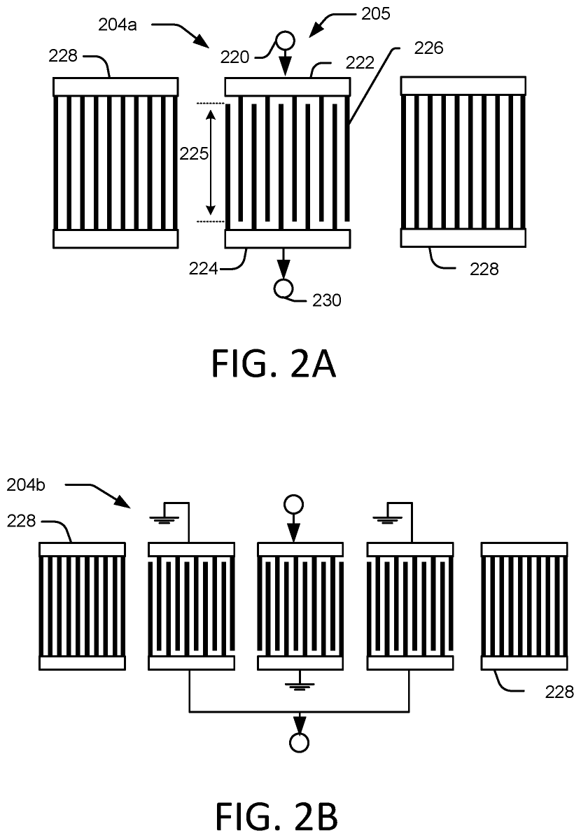

FIG. 2A is a top view of an example electrode structure 204a of an electroacoustic device (e.g., such as the electroacoustic device 100 of FIG. 1A). The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230.

A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT.

The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used for the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device (e.g., such as the electroacoustic device 100 of FIG. 1A). In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures that principles described herein may be applied to including the electrode structures 204a and 204b of FIGS. 2A and 2B.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

Electroacoustic devices such as SAW resonators are being designed to cover more frequency ranges (e.g., 500 MHz to 6 GHZ), to have higher bandwidths (e.g., up to 20%), and to have improved efficiency and performance. In general, SAW resonators are subject to nonlinearities that give rise to intermodulation distortion (IMD). For example, slight conductivity through the air or dielectric between the IDT electrodes can cause arcing and can worsen the nonlinearity, power durability, and compression of the device. Cascading the acoustic track can reduce certain amounts of intermodulation distortion, but this technique occupies increased space to implement and leads to larger SAW devices.

Notably, the relative permittivity (εᵣ) of the piezoelectric substrate influences the intermodulation (nonlinearity) characteristic of a SAW filter. Nonlinear Mason equivalent circuit models have been used to simulate the effects that substrate permittivity can have on the nonlinearity of SAW filters. Furthermore, the relative permittivity of the material separating the electrodes that form IDTs on a SAW device likewise influences the nonlinearity behavior of the device. By adjusting the relative permittivity of certain dielectric structures in a SAW device, intermodulation distortion of the device can be reduced.

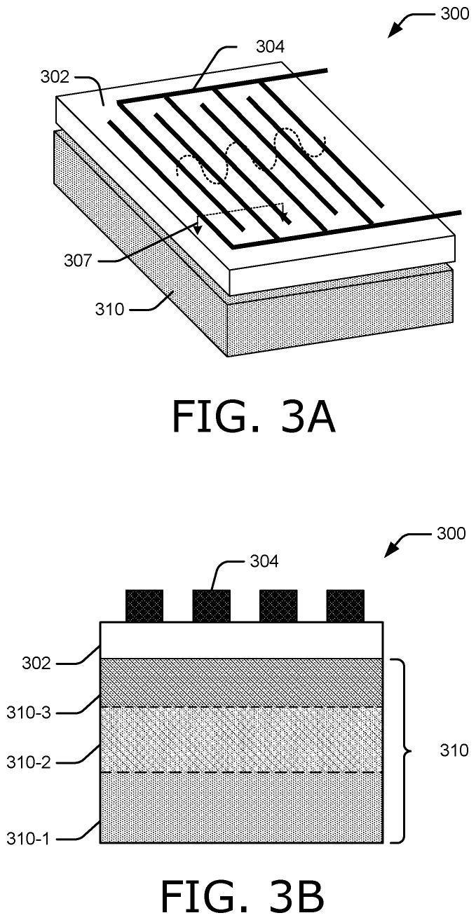

FIG. 3A is a diagram of a perspective view of another example of an electroacoustic device 300. The electroacoustic device 300 (e.g., that may be configured as or be a part of a SAW resonator) is similar to the electroacoustic device 100 of FIG. 1A but has a different layer stack. In particular, the electroacoustic device 300 includes a thin piezoelectric material 302 that is provided on a substrate 310 (e.g., silicon). The electroacoustic device 300 may be referred to as a thin-film SAW resonator or device (TF-SAW) in some cases.

Based on the type of piezoelectric material 302 used (e.g., typically having higher coupling factors relative to the electroacoustic device 100 of FIG. 1) and a controlled thickness of the piezoelectric material 302, the particular acoustic wave modes excited may be slightly different than those in the electroacoustic device 100 of FIG. 1A. Based on the design (thicknesses of the layers, and selection of materials, etc.), the electroacoustic device 300 may have a higher quality factor (Q) as compared to the electroacoustic device 100 of FIG. 1A. In general, the substrate 310 may be substantially thicker than the piezoelectric material 302 (e.g., potentially on the order of 50 to 100 times thicker as one example, or more). The substrate 310 may include other layers (or other layers may be included between the substrate 310 and the piezoelectric material 302).

FIG. 3B is a diagram of a side view of the electroacoustic device 300 of FIG. 3A showing an exemplary layer stack (along a cross-section 307). In the example shown in FIG. 3B, the substrate 310 may include sublayers such as a substrate sublayer 310-1 (e.g., of silicon) that may have a higher resistance (e.g., relative to the other layers—high resistivity layer). The substrate 310 may further include a trap rich layer 310-2 (e.g., poly-silicon). The substrate 310 may further include a compensation layer 310-3 (e.g., silicon dioxide (SiO₂) or another dielectric material) that may provide temperature compensation and other properties. These sublayers may be considered part of the substrate 310 or their own separate layers. A relatively thin piezoelectric material 302 is provided on the substrate 310 with a particular thickness for providing a particular acoustic wave mode (e.g., as compared to the electroacoustic device 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the coupling to the electrode structure 304 and acoustic velocities within the piezoelectric material in different regions of the electrode structure 304 may differ between different types of electroacoustic devices, such as between the electroacoustic device 100 of FIG. 1A and the electroacoustic device 300 of FIGS. 3A and 3B.

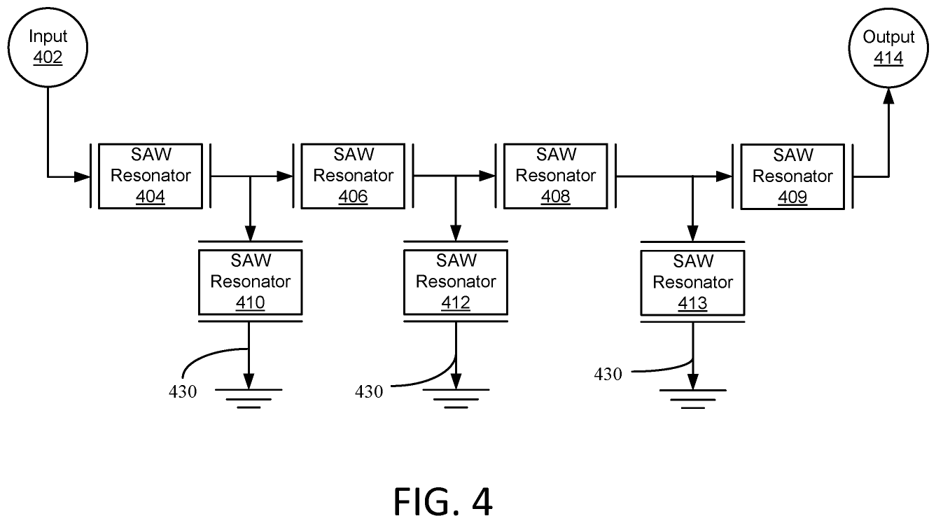

FIG. 4 illustrates a schematic diagram of an electroacoustic filter circuit 400 that may include an electroacoustic device. The electroacoustic filter circuit 400 provides one example of where SAW resonators or devices (e.g., such as the SAW resonator or device of FIG. 1A, FIG. 3A, etc.) may be used.

The electroacoustic filter circuit 400 includes an input terminal 402 and an output terminal 414. Between the input terminal 402 and the output terminal 414, a ladder-type network of SAW resonators is provided.

The electroacoustic filter circuit 400 includes a first SAW resonator 404, a second SAW resonator 406, a third SAW resonator 408, and a fourth SAW resonator 409, all electrically connected in a series path between the input terminal 402 and the output terminal 414.

The electroacoustic filter circuit 400 includes a fifth SAW resonator 410 (e.g., a shunt resonator) that has a first terminal connected between the first SAW resonator 404 and the second SAW resonator 406, and a second terminal connected to a reference potential node 430 (e.g., electric ground) for the filter circuit 400.

The electroacoustic filter circuit 400 includes a sixth SAW resonator 412 (e.g., a shunt resonator) that has a first terminal connected between the second SAW resonator 406 and the third SAW resonator 408, and a second terminal connected to the reference potential node 430.

The electroacoustic filter circuit 400 includes a seventh SAW resonator 413 (e.g., a shunt resonator) that has a first terminal connected between the third SAW resonator 408 and the fourth SAW resonator 409, and a second terminal connected to the reference potential node 430.

Each of SAW resonators 404, 406, 408, 409, 410, 412, 413 may be implemented as described with respect to the electroacoustic device 100 of FIG. 1A. Each of the SAW resonators 404, 406, 408, 409, 410, 412, 413 may include one or multiple (e.g., four) cascaded SAW resonators.

The electroacoustic filter circuit 400 may, for example, be a band pass filter circuit having a passband with a selected frequency range (e.g., in a range between 500 MHz and 6 GHz).

Better Electrostatic discharge (ESD) And Compression Behavior Through Sulfur Hexafluoride-filled SAW Thin-film Acoustic Package (TFAP) Domes

Certain aspects of the present disclosure relate to a surface acoustic wave (SAW) device with at least one thin-film acoustic package (TFAP) dome/cavity (e.g., formed between a cap layer and conductive fingers of an interdigital transducer (IDT)). The TFAP dome or cavity of the SAW device may be filled with sulfur hexafluoride (SF₆), which may have a high dielectric strength.

The presence of the SF₆ may potentially improve electrostatic discharge (ESD) performance/handling and compression behavior of the SAW device through creating a dielectric barrier hindering arching through a gas phase without additionally mass-loading the fingers of the IDT. The improved ESD performance/handling and compression behavior may also allow for area reduction (e.g., as the fingers of the IDT can be positioned closer to each other), and thus smaller size of the SAW device.

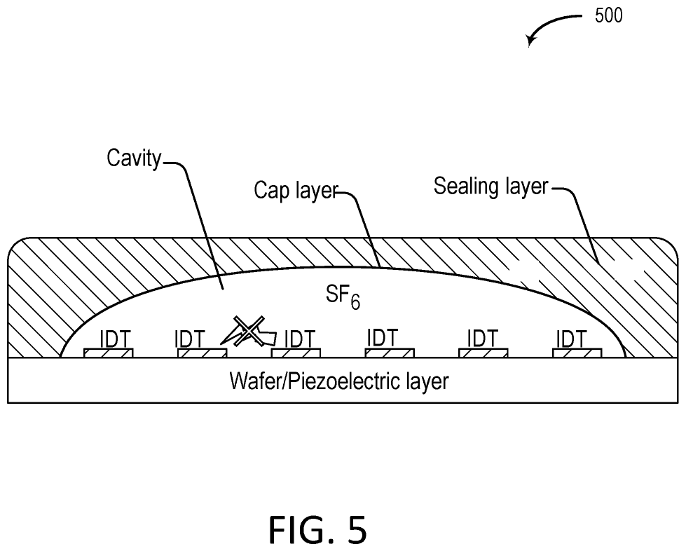

FIG. 5 is a diagram 500 of a perspective view of an example SAW device, with SF₆ filled TFAP domes may in accordance with aspects of the present disclosure.

The SAW device may include a piezoelectric layer, which may include a piezoelectric material. The piezoelectric material may be formed from a variety of materials such as quartz, lithium tantalate (LiTaO₃), lithium niobate (LiNbO₃), doped variants of these, other piezoelectric materials, or other crystals. The piezoelectric layer may also include other layers, such as a substrate material or other layers below or underneath the piezoelectric layer.

The SAW device may further include an electrode structure (e.g., an IDT) provided on (or at least above) a surface of the piezoelectric layer. The IDT may include one or more electrode fingers. In one example, the IDT may be electrically conductive and formed from metallic materials. In another example, the IDT may be formed from materials that are electrically conductive, but non-metallic (e.g., graphene). Each finger of the IDT may have a height, which may be between 80 nm to 500 nm. Although only six fingers of the IDT are shown in FIG. 5, it is to be understood that the IDT may include more or less than six fingers.

An electrical signal excited in the IDT (e.g., applying a voltage) may be transformed into an acoustic wave that propagates in a particular direction via the piezoelectric layer. The acoustic wave may be transformed back into the electrical signal and provided as an output.

The SAW device may further include a cap layer that is provided above or over the fingers of the IDT. The cap layer may be applied so that a cavity may be formed between the IDT and an under surface of the cap layer.

One or more materials may be disposed above and between the fingers of the IDT within the cavity. The material may be SF₆. In one example, the SF₆ may have a value of dielectric strength that is higher than 8 kilovolts (kV) millimeter (mm)⁻¹. The dielectric strength may be a measure of a material's insulating performance. For example, the dielectric strength may be a voltage that an insulating material can withstand before breakdown occurs. The dielectric strength may depend on a thickness of the material and on method and conditions of the test, and is measured in kVmm⁻¹, or volts per unit thickness.

The value of the dielectric strength of SF₆ is different from dielectric strength of dry air, which may have a value of 3 kVmm⁻¹. The value of the dielectric strength of SF₆ may also be different from dielectric strength of a dielectric material such as silicon dioxide (SiO₂), which may be in a range of 25-40 kVmm⁻¹.

The SAW device may further include a sealing layer, which may be provided on (or at least above) the cap layer and/or a portion of the piezoelectric layer. The sealing layer may include a polymer material.

The SAW device may further include a reinforcement layer (not shown), which may be provided on (or at least above) the sealing layer. The reinforcement layer may include silicon nitride (Si₃N₄).

The SAW device may further include a passivation layer (not shown), which may be provided on (or at least above) the IDT. In such cases, the cap layer may be applied so that the cavity may be formed between the passivation layer (on the IDT) and the under surface of the cap layer. In one example, the passivation layer may include Si₃N₄. In another example, the passivation layer may include aluminum oxide (Al₂O₃).

In some aspects, the passivation layer may also be disposed below or underneath the cap layer. In such cases, the passivation layer may be applied so that the cavity may be formed between the IDT and an under surface of the passivation layer.

The SAW device may further include a (continuous thin) dielectric layer (not shown) that may be provided on (or at least above) the piezoelectric layer (e.g., which may have a height indicating a first value) and below the IDT. In some cases, the dielectric layer may be absent. The dielectric layer may have a height indicating a second value, which may also be referred to as a thickness. It may be desirable to deposit the dielectric layer in a very thin layer to avoid loss of coupling between the piezoelectric layer and the fingers of the IDT. For example, the height of the continuous dielectric layer may be 2.5 nm. The piezoelectric layer may be substantially thicker than the dielectric layer (e.g., potentially on the order of 20,000 to 200,000 times thicker as one example, or more). Additionally, the fingers of the IDT may be substantially thicker than the dielectric layer (e.g., potentially on the order of up to 250 times thicker as one example). That is, a height of the fingers of the IDT and the height of the piezoelectric layer may be substantially greater than the height of the dielectric layer, by at least an order of magnitude.

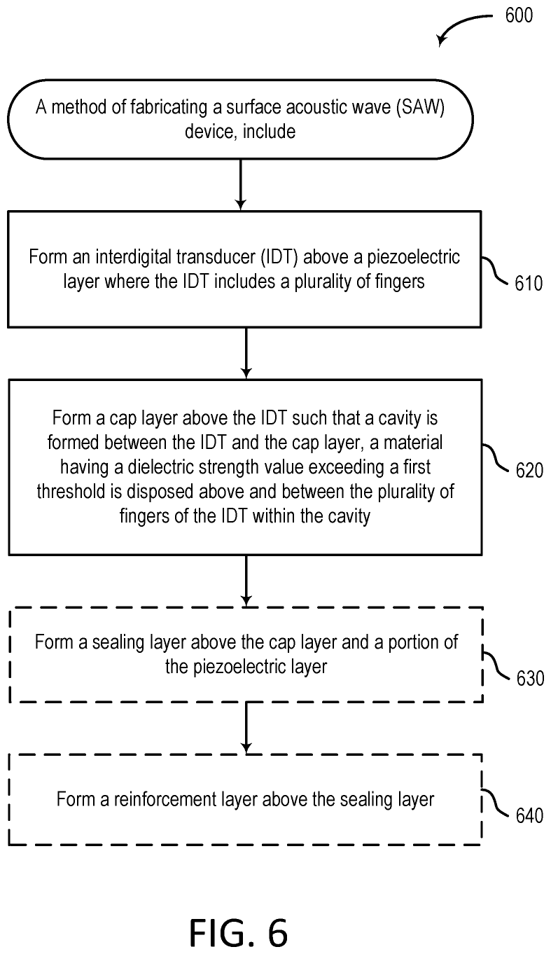

FIG. 6 is a flow diagram depicting example operations 600 for fabricating a SAW device (e.g., such as the SAW device of FIG. 5). The operations 600 are described in a form of a set of blocks that specify the operations that can be performed. However, the operations are not necessarily limited to the order shown in FIG. 6 or described herein, for the operations may be implemented in alternative orders or in fully or partially overlapping manners. Also, more, fewer, and/or different operations may be implemented to perform the operations 600. The operations 600 may be performed, for example, by a semiconductor fabrication facility (also referred to as a “fab house”).

The operations 600 may begin, at 610, with the fabrication facility forming an IDT above (e.g., adjacent to) a piezoelectric layer. Forming the IDT may include forming an electrode (e.g., of electrode structure) having a busbar and a plurality of fingers (e.g., IDT fingers) extending from the busbar.

In some aspects, the fabrication facility may form a passivation layer above the plurality of fingers of the IDT. In one example, the passivation layer may include Si₃N₄. In another example, the passivation layer may include Al₂O₃.

At 620, the fabrication facility forms a cap layer above the IDT such that a cavity is formed between the IDT and the cap layer. In one example, the cap layer may include SiO₂. In another example, the cap layer may include Si₃N₄.

In some aspects, a material having a dielectric strength value that may exceed a first threshold and but is below a second threshold may be disposed above and/or between the plurality of fingers of the IDT within the cavity. A value of the second threshold is higher than a value of the first threshold. In one example, the material may be SF₆.

In some aspects, the fabrication facility may form the passivation layer below or underneath the cap layer. In one example, the passivation layer may include Si₃N₄. In another example, the passivation layer may include Al₂O₃.

At 630, the fabrication facility may form a sealing layer above the cap layer and a portion of the piezoelectric layer. The sealing layer may include a polymer material.

At 640, the fabrication facility may form a reinforcement layer above the sealing layer. The reinforcement layer may include Si₃N₄.

Each of the layers described above may be formed using any appropriate technique for producing SAW or electroacoustic devices. For example, the layers may by formed using e-beam evaporation and lift-off processes.

### Example Electronic Devices and Wireless Transceiver Circuits

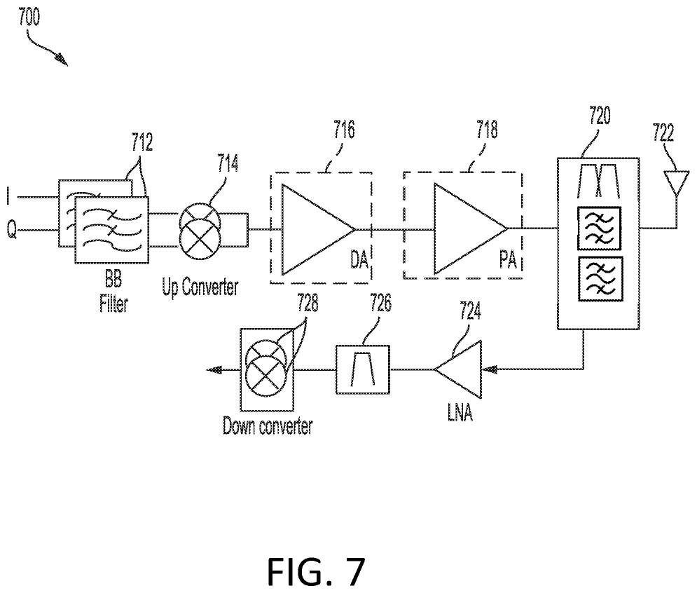

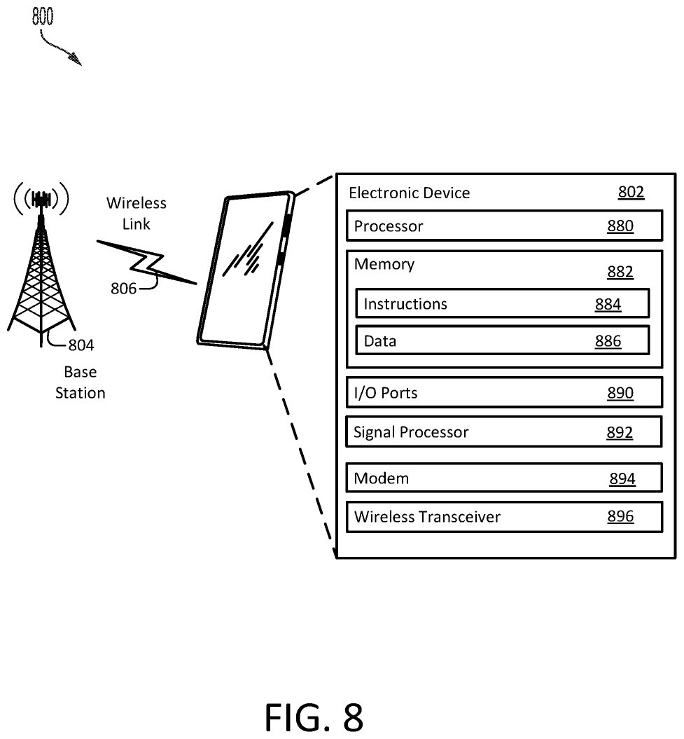

According to certain aspects of the present disclosure, the SAW device of FIG. 5 may be implemented in a filter or duplexer of a radio frequency (RF) circuit for use in a wireless communications device. Such a wireless communications device is described in the description of FIGS. 7-8.

FIG. 7 is a functional block diagram of at least a portion of an example of a simplified wireless transceiver circuit 700 in which the electroacoustic filter circuit 400 of FIG. 4 may be employed. The transceiver circuit 700 is configured to receive signals/information for transmission (shown as in-phase (I) and quadrature (Q) values) which is provided to one or more baseband (BB) filters 712. The filtered output is provided to one or more mixers 714 for up conversion to RF) signals. The output from the one or more mixers 714 may be provided to a driver amplifier (DA) 716 whose output may be provided to a power amplifier (PA) 718 to produce an amplified signal for transmission. The amplified signal is output to the antenna 722 through one or more filters 720 (e.g., duplexers if used as a frequency division duplex transceiver or other filters). The one or more filters 720 may include the electroacoustic filter circuit 400 of FIG. 4.

The antenna 722 may be used for both wirelessly transmitting and receiving data. The transceiver circuit 700 includes a receive path through the one or more filters 720 to be provided to a low noise amplifier (LNA) 724 and a further filter 726 and then downconverted from the receive frequency to a baseband frequency through one or more mixer circuits 728 before the signal is further processed (e.g., provided to an analog-to-digital converter (ADC) and then demodulated or otherwise processed in the digital domain). There may be separate filters for the receive circuit (e.g., may have a separate antenna or have separate receive filters) that may be implemented using the electroacoustic filter circuit 400 of FIG. 4.

FIG. 8 is a diagram of an environment 800 that includes an electronic device 802, in which aspects of the present disclosure may be practiced. In the environment 800, the electronic device 802 communicates with a base station 804 through a wireless link 806. As shown, the electronic device 802 is depicted as a smartphone. However, the electronic device 802 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 804 communicates with the electronic device 802 via the wireless link 806, which may be implemented as any suitable type of wireless link. Although depicted as a base station tower of a cellular radio network, the base station 804 may represent or be implemented as another device, such as a satellite, terrestrial broadcast tower, access point, peer-to-peer device, mesh network node, fiber optic line, another electronic device generally as described above, and so forth. Hence, the electronic device 802 may communicate with the base station 804 or another device via a wired connection, a wireless connection, or a combination thereof. The wireless link 806 can include a downlink of data or control information communicated from the base station 804 to the electronic device 802 and an uplink of other data or control information communicated from the electronic device 802 to the base station 804. The wireless link 806 may be implemented using any suitable communication protocol or standard, such as 3rd Generation Partnership Project Long-Term Evolution (3GPP LTE), 3GPP NR 5G, IEEE 802.11, IEEE 802.16, Bluetooth™, and so forth.

The electronic device 802 includes a processor 880 and a memory 882. The memory 882 may be or form a portion of a computer-readable storage medium. The processor 880 may include any type of processor, such as an application processor or a multi-core processor, that is configured to execute processor-executable instructions (e.g., code) stored by the memory 882. The memory 882 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 882 is implemented to store instructions 884, data 886, and other information of the electronic device 802, and thus when configured as or part of a computer-readable storage medium, the memory 882 does not include transitory propagating signals or carrier waves.

The electronic device 802 may also include input/output ports 890. The I/O ports 890 enable data exchanges or interaction with other devices, networks, or users or between components of the device.

The electronic device 802 may further include a signal processor (SP) 892 (e.g., such as a digital signal processor (DSP)). The signal processor 892 may function similar to the processor and may be capable of executing instructions and/or processing information in conjunction with the memory 882.

For communication purposes, the electronic device 802 also includes a modem 894, a wireless transceiver 896, and an antenna (not shown). The wireless transceiver 896 provides connectivity to respective networks and other electronic devices connected therewith using radio-frequency (RF) wireless signals and may include the transceiver circuit 700 of FIG. 7. The wireless transceiver 796 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

### EXAMPLE ASPECTS/CLAUSES

In addition to the various aspects described above, specific combinations of aspects are within the scope of the disclosure, some of which are detailed in the clauses below:

Clause 1: A surface acoustic wave (SAW) device comprising: a piezoelectric layer; an interdigital transducer (IDT) disposed above the piezoelectric layer, wherein the IDT comprises a plurality of fingers; a cap layer disposed above the IDT, wherein a cavity is formed between the IDT and the cap layer; and a material having a dielectric strength value exceeding a first threshold disposed above and between the plurality of fingers of the IDT within the cavity.

Clause 2: The SAW device of Clause 1, wherein: the dielectric strength value is below a second threshold; and a value of the second threshold is higher than a value of the first threshold.

Clause 3: The SAW device of any of Clauses 1-2, wherein the material comprises sulfur hexafluoride (SF₆).

Clause 4: The SAW device of any of Clauses 1-3, wherein the cap layer comprises silicon dioxide (SiO₂).

Clause 5: The SAW device of any of Clauses 1-4, wherein the cap layer comprises silicon nitride (Si3N4).

Clause 6: The SAW device of any of Clauses 1-5, further comprising a passivation layer disposed above the IDT, wherein the passivation layer comprises silicon nitride (Si3N4) or aluminum oxide (Al₂O₃).

Clause 7: The SAW device of any of Clauses 1-6, further comprising a passivation layer disposed below the cap layer, wherein the passivation layer comprises silicon nitride (Si3N4) or aluminum oxide (Al₂O₃).

Clause 8: The SAW device of any of Clauses 1-7, further comprising a sealing layer disposed above the cap layer and a portion of the piezoelectric layer, and wherein the sealing layer comprises a polymer material.

Clause 9: The SAW device of Clause 8, further comprising a reinforcement layer disposed above the sealing layer, wherein the reinforcement layer comprises silicon nitride (Si3N4).

Clause 10: The SAW device of Clause 1, further comprising a plurality of resonators forming a filter circuit, wherein the SAW device of Clause 1 is a resonator in the plurality of resonators.

Clause 11: A wireless device comprising: a radio frequency (RF) circuit; and a surface acoustic wave (SAW) device coupled to the RF circuit, the SAW device comprising: a piezoelectric layer; an interdigital transducer (IDT) disposed above the piezoelectric layer, wherein the IDT comprises a plurality of fingers; a cap layer is disposed above the IDT, wherein a cavity is formed between the IDT and the cap layer; and a material having a dielectric strength value exceeding a first threshold is disposed above and between the plurality of fingers of the IDT within the cavity.

Clause 12: The wireless device of Clause 11, wherein the RF circuit comprises a transmit path and a receive path and wherein the SAW device forms a portion of a duplexer coupled to an output of the transmit path and to an input of the receive path.

Clause 13: The wireless device of Clause 11, wherein: the RF circuit comprises a low-noise amplifier (LNA); and the SAW device is coupled to an output of the LNA.

Clause 14: A method of fabricating a surface acoustic wave (SAW) device, the method comprising: forming an interdigital transducer (IDT) above a piezoelectric layer, wherein the IDT comprises a plurality of fingers; and forming a cap layer above the IDT such that a cavity is formed between the IDT and the cap layer, wherein a material having a dielectric strength value exceeding a first threshold is disposed above and between the plurality of fingers of the IDT within the cavity.

Clause 15: The method of Clause 14, wherein: the dielectric strength value is below a second threshold; and a value of the second threshold is higher than a value of the first threshold.

Clause 16: The method of any of Clauses 14-15, wherein the material comprises sulfur hexafluoride (SF₆).

Clause 17: The method of any of Clauses 14-16, wherein the cap layer comprises silicon dioxide (SiO₂).

Clause 18: The method of any of Clauses 14-17, wherein the cap layer comprises silicon nitride (Si3N4).

Clause 19: The method of any of Clauses 14-18, further comprising forming a sealing layer above the cap layer and a portion of the piezoelectric layer.

Clause 20: The method of Clause 19, wherein the sealing layer comprises a polymer material.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of example, an element, or any portion of an element, or any combination of elements described herein may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoCs), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A surface acoustic wave (SAW) device comprising:
a piezoelectric layer;
an interdigital transducer (IDT) disposed above the piezoelectric layer, wherein the IDT comprises a plurality of fingers;
a cap layer disposed above the IDT, wherein a cavity is formed between the IDT and the cap layer; and
a material having a dielectric strength value exceeding a first threshold disposed above and between the plurality of fingers of the IDT within the cavity.

2. The SAW device of claim 1, wherein:
the dielectric strength value is below a second threshold; and
a value of the second threshold is higher than a value of the first threshold.

3. The SAW device of claim 1, wherein the material comprises sulfur hexafluoride (SF₆).

4. The SAW device of claim 1, wherein the cap layer comprises silicon dioxide (SiO₂).

5. The SAW device of claim 1, wherein the cap layer comprises silicon nitride (Si3N4).

6. The SAW device of claim 1, further comprising a passivation layer disposed above the IDT, wherein the passivation layer comprises silicon nitride (Si3N4) or aluminum oxide (Al₂O₃).

7. The SAW device of claim 1, further comprising a passivation layer disposed below the cap layer, wherein the passivation layer comprises silicon nitride (Si3N4) or aluminum oxide (Al₂O₃).

8. The SAW device of claim 1, further comprising a sealing layer disposed above the cap layer and a portion of the piezoelectric layer, and wherein the sealing layer comprises a polymer material.

9. The SAW device of claim 8, further comprising a reinforcement layer disposed above the sealing layer, wherein the reinforcement layer comprises silicon nitride (Si3N4).

10. A plurality of resonators forming a filter circuit, wherein the SAW device of claim 1 is a resonator in the plurality of resonators.

11. A wireless device comprising:
a radio frequency (RF) circuit; and
a surface acoustic wave (SAW) device coupled to the RF circuit, the SAW device comprising:
a piezoelectric layer;
an interdigital transducer (IDT) disposed above the piezoelectric layer, wherein the IDT comprises a plurality of fingers;
a cap layer is disposed above the IDT, wherein a cavity is formed between the IDT and the cap layer; and
a material having a dielectric strength value exceeding a first threshold is disposed above and between the plurality of fingers of the IDT within the cavity.

12. The wireless device of claim 11, wherein the RF circuit comprises a transmit path and a receive path and wherein the SAW device forms a portion of a duplexer coupled to an output of the transmit path and to an input of the receive path.

13. The wireless device of claim 11, wherein:
the RF circuit comprises a low-noise amplifier (LNA); and
the SAW device is coupled to an output of the LNA.

14. A method of fabricating a surface acoustic wave (SAW) device, the method comprising:
forming an interdigital transducer (IDT) above a piezoelectric layer, wherein the IDT comprises a plurality of fingers; and
forming a cap layer above the IDT such that a cavity is formed between the IDT and the cap layer, wherein a material having a dielectric strength value exceeding a first threshold is disposed above and between the plurality of fingers of the IDT within the cavity.

15. The method of claim 14, wherein:
the dielectric strength value is below a second threshold; and
a value of the second threshold is higher than a value of the first threshold.

16. The method of claim 14, wherein the material comprises sulfur hexafluoride (SF₆).

17. The method of claim 14, wherein the cap layer comprises silicon dioxide (SiO₂).

18. The method of claim 14, wherein the cap layer comprises silicon nitride (Si3N4).

19. The method of claim 14, further comprising forming a sealing layer above the cap layer and a portion of the piezoelectric layer.

20. The method of claim 19, wherein the sealing layer comprises a polymer material.
